(19) United States
(12) Patent Application Publication
(10) Pub. No.: US 2011/0133795 A1
(43) Pub. Date: Jun. 9, 2011

(54) DIGITAL PHASE-LOCKED LOOP WITH REDUCED LOOP DELAY

(75) Inventors: Gyu Suck KIM, Seoul (KR); Seong Hwan CHO, Daejeon (KR); Woo Kon SON, Daegu (KR)

(73) Assignees: SAMSUNG ELECTRO-MECHANICS CO., LTD., Gyunggi-do (KR); KOREA ADVANCED INSTITUTE OF SCIENCE AND TECHNOLOGY, Daejeon (KR)

(21) Appl. No.: 12/790,242

(22) Filed: May 28, 2010

(30) Foreign Application Priority Data
Dec. 4, 2009 (KR) 10-2009-0119924

(51) Int. Cl. H03L 7/08

(52) U.S. Cl. 327/156

(57) ABSTRACT

There is provided a digital phase-locked loop. A digital phase-locked loop according to an aspect of the invention may include: a reference phase accumulation unit outputting a reference sampling phase value; a phase detection unit detecting a phase difference signal; a digital loop filter filtering and averaging the phase difference signal from the phase detection unit; a digitally controlled oscillator generating an oscillation signal having a predetermined frequency; a DOC phase accumulation unit outputting the DCO sampling phase value, and generating a plurality of first to n-th D-FFs having the same frequency and different phases delayed in a sequential manner; and first to n-th D-FFs included in a closed loop including the phase detection unit, the digital loop filter, the digitally controlled oscillator, and the DOC phase accumulation unit, and operating according to the plurality of first to n-th clock signals from the DCO phase accumulation unit, respectively.

### CROSS-REFERENCE TO RELATED APPLICATIONS

This application claims the priority of Korean Patent Application No. 10-2009-0119924 filed on Dec. 4, 2009, in the Korean Intellectual Property Office, the disclosure of which is incorporated herein by reference.

### BACKGROUND OF THE INVENTION

1. Field of the Invention

The present invention relates to a digital phase locked loop that can be applied to a wireless communications system, and more particularly, to a digital phase locked loop with reduced loop delay that can reduce delay in a closed loop of a digital phase-locked loop by using multi-phase signals having phases and higher frequency than a reference signal.

2. Description of the Related Art

In general, an A/D converter, a clock generator producing clocks for a microprocessor, or a frequency synthesizer, which is the core component of a wireless communications system, is manufactured on the basis of a phase locked loop.

Typically, phase-locked loops have been designed using analog circuits such as a voltage controlled oscillator (VCO), a charge pump, or a loop filter. However, these analog circuits are sensitive to process, voltage, and temperature (PVT) variations, which need to be considered when designing phase-locked loops. Therefore, research has been conducted into all digital phase locked loops (All_Digital_PLL) in order to switch analog circuits, being used to design analog phase locked loops, to digital circuits.

Considerations, involved in designing these all digital phase locked loops, may include phase noise and stability. Phase noise, especially, is considered to be the most important factor in evaluating the performance of an all digital PLL. In general, the phase noise of this all digital PLL is determined by quantization noise generated from a phase comparator (PD) and noise generated from a digitally controlled oscillator. Furthermore, stability is a basic factor that needs to be taken into account when designing an all digital PLL.

The components of the all digital PLL operate in such a manner that the components are synchronized with reference signals. Therefore, the components thereof unavoidably have loop delay. However, one report says that the performance of the all digital PLL may be reduced due to this phase delay in terms of phase noise and stability.

In the related art, a digital phase-locked loop includes a reference phase accumulation unit, a DCO phase accumulation unit, a phase detection unit, a digital loop filter, and a digitally controlled oscillator. The reference phase accumulation unit accumulates a value corresponding to a predetermined frequency control word (FCW) during each reference clock cycle and samples the value being accumulated during each reference clock cycle to thereby supply a reference sampling value. The DOC phase accumulation unit accumulates a value corresponding to “1” during each DCO clock cycle and samples the value being accumulated during each reference clock cycle to thereby supply a DCO sampling value. The phase detection unit detects phase difference information corresponding to a difference value between the reference sampling value and the DCO sampling value. The digital loop filter averages the phase difference information detected by the phase detection unit. The digitally controlled oscillator generates an oscillation signal on the basis of the averaged digital phase difference information.

Here, the digital phase-locked loop, according to the related art, may further include a delta signal modulator (DSM) that converts the digital phase difference information from the digital loop filter according to the resolution of the digitally controlled oscillator. That is, the delta sigma modulator (DSM) modulates the digital phase difference information from the digital loop filter into phase difference information appropriate for the resolution of the digitally controlled oscillator.

However, in the digital phase-locked loop according to the related art, the reference phase accumulation unit, the DCO phase accumulation unit, the digital loop, and the delta sigma modulator each include a D-FF in order to perform set operations. Therefore, as shown in FIG. 1, a digital phase-locked loop according to the related art includes a plurality of D-FFs in a closed loop.

FIG. 1 is a block diagram illustrating a D-FF circuit of a digital phase-locked loop according to the related art. FIG. 2 is a timing chart illustrating the D-FF circuit of the digital phase-locked loop according to the related art as shown in FIG. 1.

Referring to FIGS. 1 and 2, the D-FF circuit of the digital phase-locked loop according to the related art may include, for example, first, second, third and fourth D-FFs that operate according to one clock signal ref1.

That is, the first D-FF samples a signal being input at a rising edge of a first clock of the clock signal ref1, and outputs the sampled signal to an output Q1. The second D-FF samples a signal being input at a rising edge of a second clock of the clock signal ref1, and outputs the sampled signal to an output Q2. The third D-FF samples a signal being input at a rising edge of a third clock of the clock signal ref1, and outputs the sampled signal to an output Q3. The fourth D-FF samples a signal being input at a rising edge of a fourth clock of the clock signal ref1, and outputs the sampled signal to an output Q4.

According to this operation, a delay corresponding to almost three clock cycles is made between a time at which the first D-FF samples a signal and a time at which the fourth D-FF samples a signal.

As described above, in the digital phase-locked loop according to the related art, loop delay is caused, which generates phase noise and reduces stability.

### SUMMARY OF THE INVENTION

An aspect of the present invention provides a digital phase-locked loop with reduced loop delay that can reduce delay in a closed loop of a digital phase-locked loop by using multi-phase signals having a higher frequency than a reference signal and having phases.

According to an aspect of the present invention, there is provided a digital phase-locked loop including: a reference phase accumulation unit accumulating a predetermined division value according to a reference clock and sampling the predetermined division value being accumulated to thereby output a reference sampling phase value; a phase detection unit detecting a phase difference signal corresponding to a difference value between the reference sampling phase value from the reference phase accumulation unit and a DCO sampling phase value; a digital loop filter filtering and averaging the phase difference signal from the phase detection unit; a digitally controlled oscillator generating an oscillation signal having a predetermined frequency on the basis of the phase difference signal averaged by the digital loop filter; a DOC phase accumulation unit accumulating a predetermined reference value according to the oscillation signal from the digitally controlled oscillator, sampling the predetermined reference value being accumulated to thereby output the DCO sampling phase value, and generating a plurality of first to n-th D-FFs having the same frequency higher than a reference clock and different phases delayed in a sequential manner; and first to n-th D-FFs included in a closed loop including the phase detection unit, the digital loop filter, the digitally controlled oscillator, and the DOC phase accumulation unit, and operating according to the plurality of first to n-th clock signals from the DCO phase accumulation unit, respectively.

The DCO phase accumulation unit may generate the plurality of first to n-th clock signals having the same frequency and different phases delayed in a sequential manner by using the oscillation signal.

The DCO phase accumulation unit may include: an accumulator accumulating the predetermined reference value according to the oscillation signal from the digitally controlled oscillator; and a D-FF sampling the predetermined reference value accumulated by the accumulator to thereby output the DCO sampling phase value, wherein the accumulator generates the plurality of first to n-th clock signals having the same frequency and different phases delayed in a sequential manner by using the oscillation signal.

The digital phase-locked loop further may include a delta sigma modulator modulating the phase difference signal from the digital loop filter into a signal suitable for resolution of the digitally controlled oscillator.

The delta sigma modulator may include a plurality of D-FFs operating according to the plurality of first to n-th clock signals from the DCO phase accumulation unit.

The DCO phase accumulation unit may have a phase delay interval between a k-th clock signal and a k+1 clock signal among the plurality of first to n-th clock signals, which is shorter than one period of the first clock signal.

The DCO phase accumulation unit may have a phase delay interval between the first clock signal and the n-th clock signal among the plurality of first to n-th clock signals, which is shorter than one period of the first clock signal.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a block diagram illustrating a D-FF circuit of a digital phase-locked loop according to the related art;

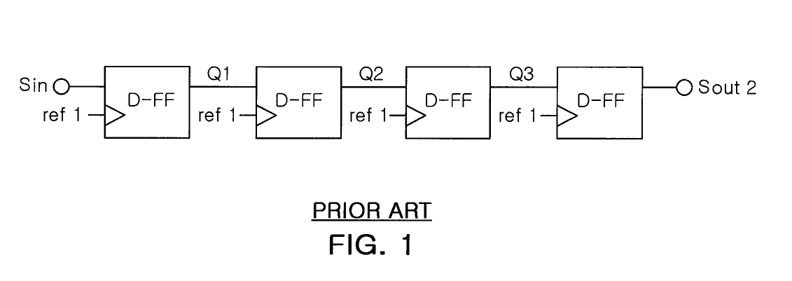

FIG. 2 is a timing chart illustrating the D-FF circuit of the digital phase-locked loop according to the related art as shown in FIG. 1;

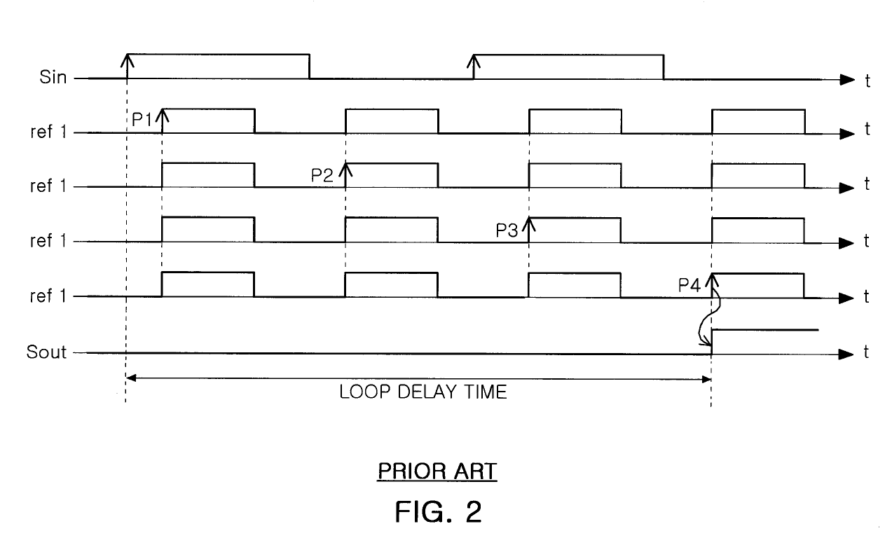

FIG. 3 is a block diagram illustrating a digital phase-locked loop according to an exemplary embodiment of the present invention;

FIG. 4 is a view illustrating the operation of an accumulator of a DCO phase accumulation unit according to an exemplary embodiment of the present invention;

FIG. 5 is a block diagram illustrating a D-FF circuit of a digital phase-locked loop according to an exemplary embodiment of the present invention;

FIG. 6 is an exemplary view illustrating a D-FF circuit of a digital phase-locked loop according to an exemplary embodiment of the present invention; and

FIG. 7 is a timing chart illustrating a D-FF circuit of a digital phase-locked loop according to an exemplary embodiment of the present invention.

### DETAILED DESCRIPTION OF THE PREFERRED EMBODIMENT

Exemplary embodiments of the present invention will now be described in detail with reference to the accompanying drawings.

The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions may be exaggerated for clarity, and the same reference numerals will be used throughout to designate the same or like components.

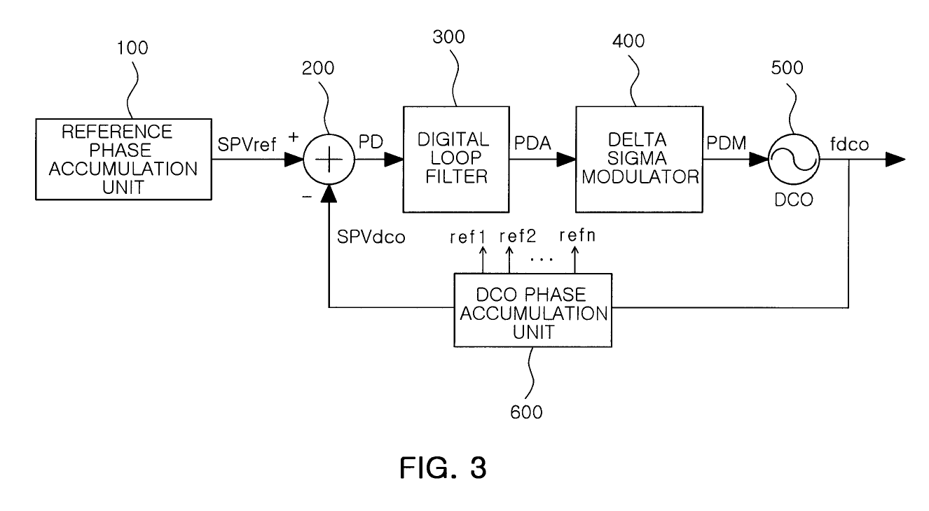

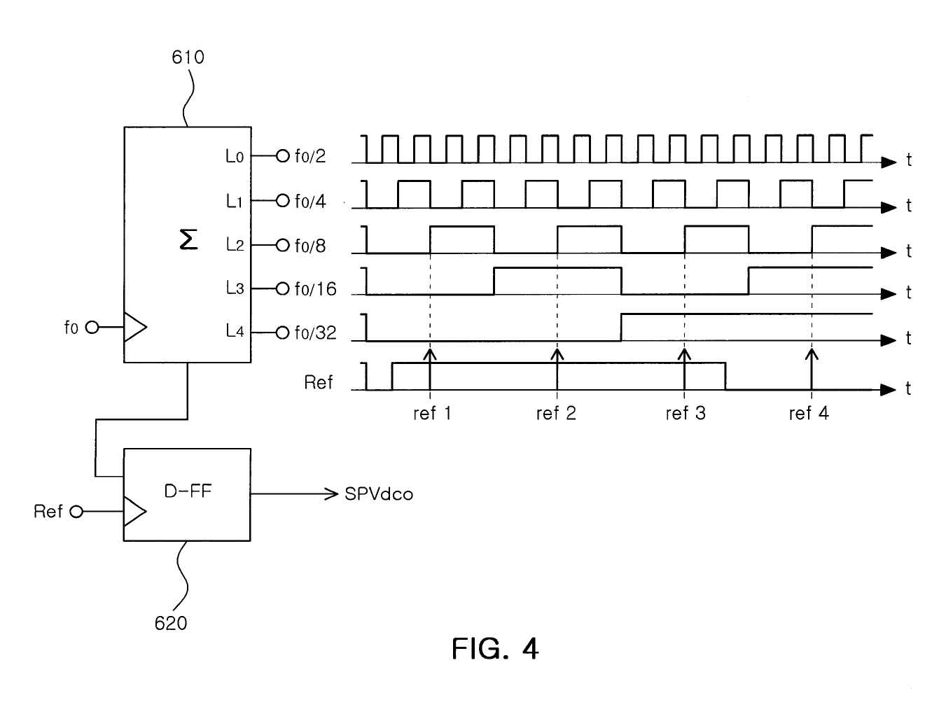

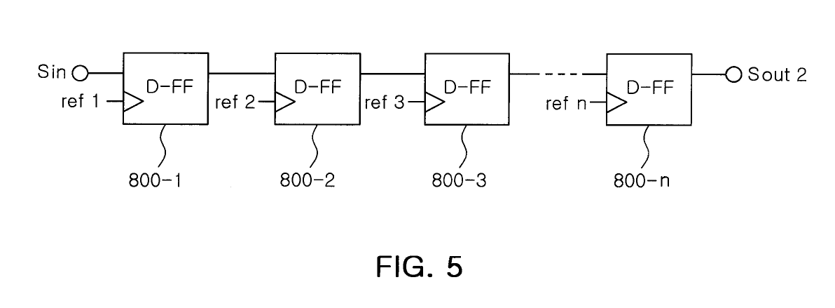

FIG. 3 is a block diagram illustrating a digital phase-locked loop according to an exemplary embodiment of the invention. FIG. 4 is a view illustrating the operation of an accumulator of a DCO phase accumulation unit according to an exemplary embodiment of the invention. FIG. 5 is a block diagram illustrating a D-FF circuit of a digital phase-locked loop according to an exemplary embodiment of the invention.

Referring to FIGS. 3 through 5, a digital phase-locked loop according to this embodiment may include a reference phase accumulation unit 100, a phase detection unit 200, a digital loop filter 300, a digitally controlled oscillator 500, a DCO phase accumulation unit 600, and first to n-th D-FFs 800-1 to 800-n. The reference phase accumulation unit 100 accumulates a predetermined division value according to a reference clock and samples the predetermined division value being accumulated to thereby output a reference sampling phase value SPVref. The phase detection unit 200 detects a phase difference signal corresponding to a difference value between the reference sampling phase value SPVref from the reference phase accumulation unit 100 and a DCO sampling phase value SPVdco. The digital loop filter 300 filters and averages a phase difference signal PD from the phase detection unit 200. The digitally controlled oscillator 500 generates an oscillation signal fdco having a predetermined frequency on the basis of an averaged phase difference signal PDA obtained by averaging the phase difference signal by the digital loop filter 300. The DCO phase accumulation unit 600 accumulates a predetermined reference value according to the oscillation signal fdco from the digitally controlled oscillator 500, samples the predetermined reference value being accumulated to thereby output the DCO sampling phase value SPVdco, and generates a plurality of first to n-th clock signals ref1 to refn having the same frequency, which is higher than the reference clock, and different phases delayed in a sequential manner. The first to n-th D-FFs 800-1 to 800-n are included in a closed loop including the phase detection unit 200, the digital loop filter 300, the digitally controlled oscillator 500, and the DCO phase accumulation unit 600, and operate according to the plurality of first to n-th clock signals ref1 to refn from the DCO phase accumulation unit 600, respectively.

Here, the division value may be set to “1”, and the reference value may be set to “1” or larger (for example, 100).

The DCO phase accumulation unit 600 may generate the plurality of first to n-th clock signals ref1 to refn that have the same frequency and different phases delayed in a sequential manner by using the oscillation signal fdco.

Referring to FIG. 4, the DCO phase accumulation unit 600 includes an accumulator 610 that accumulates the predetermined reference value according to the oscillation signal from the digitally controlled oscillator 500, and a D-FF 620 that samples the predetermined reference value being accumulated by the accumulator 610 to thereby output the DCO sampling phase value SPVdco.

Here, the accumulator 610 may generate the plurality of first to n-th clock signals ref1 to refn that have the same frequency and different phases delayed in a sequential manner by using the oscillation signal fdco(=fo).

Furthermore, referring to FIG. 3, the digital phase-locked loop may include a delta sigma modulator 400 that modulates the phase difference signal from the digital loop filter 300 into a signal appropriate for the resolution of the digitally controlled oscillator 500.

Here, the delta sigma modulator 400 may include a plurality of D-FFs that operate according to the plurality of first to n-th clock signals ref1 to refn of the DCO phase accumulation unit 600, respectively.

FIG. 5 is a block diagram illustrating a D-FF circuit of a digital phase-locked loop according to an exemplary embodiment of the invention. Referring to FIG. 5, the digital phase-locked loop according to this embodiment may include the plurality of first to n-th D-FFs 800-1 to 800-n.

The plurality of first to n-th D-FFs 800-1 to 800-n may operate according to the plurality of first to n-th clock signals ref1 to refn from the DCO phase accumulation unit 600, respectively.

A phase delay interval between a k-th clock signal refk and a k+1-th clock signal refk+1 among the plurality of first to n-th clock signals ref1 to refn may be shorter than one period of the first clock signal ref1.

In particular, in the DCO phase accumulation unit 600, a phase delay interval between the first clock signal ref1 and the n-th clock signal refn among the plurality of first to n-th clock signals ref1 to refn may be shorter than one period of the first clock signal ref1.

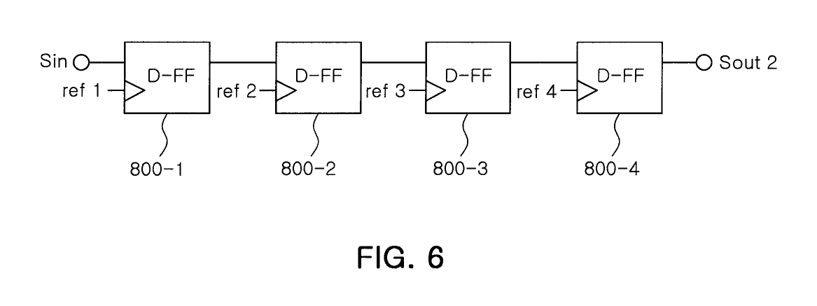

FIG. 6 is an exemplary view illustrating a D-FF circuit of a digital phase-locked loop according to an exemplary embodiment of the invention. For example, the digital phase-locked loop according to this embodiment may include the plurality of first to fourth D-FFs 800-1 to 800-4.

The first to fourth D-FFs 800-1 to 800-4 may operate according to the plurality of first to fourth clock signals ref1 to ref4 from the DCO phase accumulation unit 600.

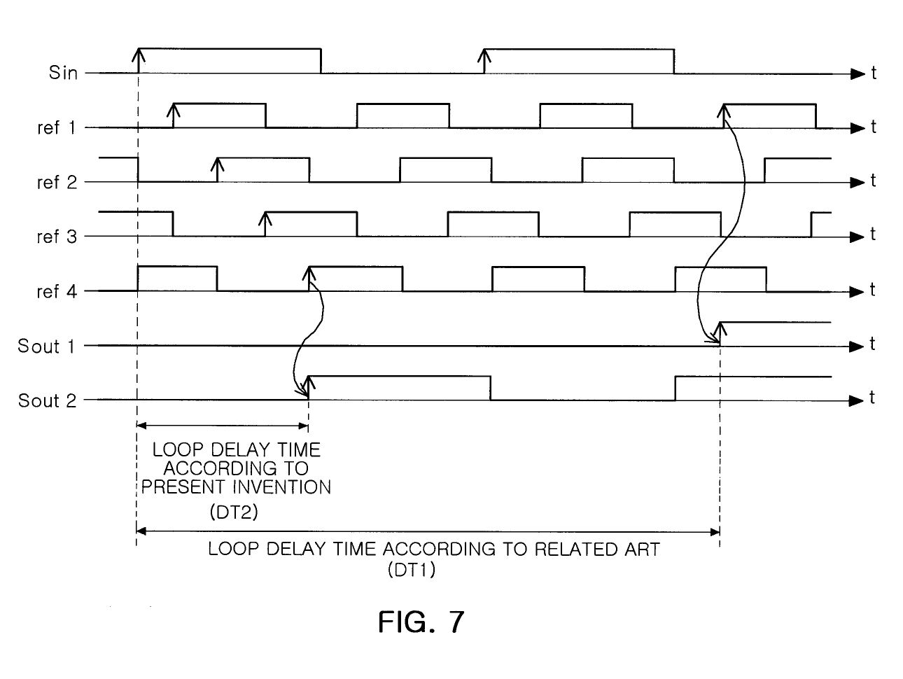

FIG. 7 is a timing chart illustrating a D-FF circuit of a digital phase-locked loop according to an exemplary embodiment of the invention. In FIG. 7, a reference character Sin denotes an input signal, and reference characters ref1, ref2, ref3, and ref4 denote first, second, third, and fourth clock signals, respectively. A reference character Sout1 denotes an output signal from a D-FF circuit of a digital phase-locked loop according to the related art, and a reference character Sout2 is an output signal from a D-FF circuit of a digital phase-locked loop according to an exemplary embodiment of the invention.

Hereinafter, the operation and effects of the invention will be described in detail with reference to the accompanying drawings.

A digital phase-locked loop according to an exemplary embodiment of the invention will be described with reference to FIGS. 3 through 7. In FIG. 3, the reference phase accumulation unit 100 of the digital phase-locked loop according to this embodiment accumulates a predetermined division value according to a reference clock and samples the predetermined division value being accumulated to thereby output the reference sampling phase value SPVref to the phase detection unit 200.

The phase detection unit 200 detects the phase difference signal corresponding to a difference value between the reference sampling phase value SPVref from the reference phase accumulation unit 100 and the DCO sampling phase value SPVdco.

The digital loop filter 300 filters the phase difference signal PD from the phase detection unit 200 to thereby output an averaged phase difference signal to the digitally controlled oscillator 500.

The digitally controlled oscillator 500 generates the oscillation signal fdco having a predetermined frequency on the basis of the phase difference signal PDA averaged by the digital loop filter 300.

The DCO phase accumulation unit 600 accumulates a predetermined reference value according to the oscillation signal fdco from the digitally controlled oscillator 500 and samples the predetermined reference value being accumulated to thereby output the DCO sampling phase value SPVdco.

Furthermore, the DCO phase accumulation unit 600 generates the plurality of first to n-th clock signals ref1 to refn having the same frequency, which is higher than the reference clock, and different phases delayed in a sequential manner.

For example, as shown in FIG. 4, the DCO phase accumulation unit 600 may generate the plurality of first to n-th clock signals ref1 to refn that have the same frequency and different phases delayed in a sequential manner by using the oscillation signal fdco.

Referring to FIG. 4, the DCO phase accumulation unit 600 may include the accumulator 610 and the D-FF 620. Here, the accumulator 610 accumulates the predetermined reference value according to the oscillation signal from the digitally controlled oscillator 500 to thereby output the predetermined reference value being accumulated to the D-FF 620.

The D-FF 620 samples the predetermined reference value being accumulated from the accumulator 610 to thereby output the DCO sampling phase value SPVdco. Here, the accumulator 610 generates the plurality of first to n-th clock signals ref1 to refn having the same frequency and different phases delayed in a sequential manner by using the oscillation signal fdco.

For example, referring to FIG. 4, in this embodiment, on the assumption that a reference clock is 26 MHz, and an oscillation signal fdco has a frequency of 800 MHz, when the frequency of the oscillation signal is divided into ½ (fo/2), the frequency thereof becomes 400 GHz. When the frequency of the oscillation signal is divided into ¼ (fo/4), the frequency thereof becomes 200 MHz. When frequency of the oscillation signal is divided into ⅛ (fo/8), the frequency thereof becomes 100 MHz. A clock signal having the frequency of 100 MHz, obtained by dividing the frequency of the oscillation signal into ⅛ (fo/8), can be used.

Therefore, by controlling the time at which the clock signal having a frequency of 100 MHz is shifted, the plurality of clock signals can be included within one cycle of the reference clock.

Referring to FIG. 3, in the digital phase-locked loop PLL according to this embodiment, the first to n-th D-FFs 800-1 to 800-n are included in the closed loop including the phase detection unit 200, the digital loop filter 300, the digitally controlled oscillator 500, and the DCO phase accumulation unit 600.

For example, the digital loop filter 300 includes at least one D-FF, and the DCO phase accumulation unit 600 also includes at least one D-FF. Furthermore, another D-FF may be further included in the digital phase-locked loop.

This D-FF performs signal sampling according to clocks. When two or more D-FFs operate according to the same clock signal, the first D-FF operates according to the first clock, and the second D-FF operates according to the second clock. Therefore, when a plurality of D-FFs operate according to clock signals having the same phase, loop delay is unavoidable.

In order to solve this loop delay problem in the digital phase-locked loop according to the related art, a plurality of clock signals, which are supplied to a plurality of D-FFs, are set to have phases in a digital phase-locked loop according to an exemplary embodiment of the invention.

Therefore, the first to n-th D-FFs 800-1 to 800-n operate according to the plurality of first to n-th clock signals ref1 to refn from the DCO phase accumulation unit 600, respectively.

Meanwhile, the digital phase-locked loop may further include the delta sigma modulator 400. Here, the delta sigma modulator 400 may modulate the phase difference signal from the digital loop filter 300 into a signal appropriate for the resolution of the digitally controlled oscillator 500.

Furthermore, the delta sigma modulator 400 may include a plurality of D-FFs in order to perform the above-described operation. The plurality of D-FFs of the delta sigma modulator 400 may also operate according to the plurality of first to n-th clock signals ref1 to refn from the DCO phase accumulation unit 600.

In the digital phase-locked loop according to this embodiment, in order to reduce loop delay, a phase delay interval between the k-th clock signal refk and the k+1-th clock signal refk+1, among the plurality of first to n-th clock signals ref1 to refn, may be set to be shorter than one period of the first clock signal ref1.

In particular, in order to further reduce loop delay, as shown in FIG. 6, in the DCO phase accumulation unit 600, a phase delay interval between the first clock signal ref1 and the n-th clock signal refn among the plurality of first to n-th clock signals ref1 to refn may be set to be shorter than one period of the first clock signal ref1.

For example, as shown in FIG. 6, the digital phase-locked loop according to this embodiment may include the plurality of first to fourth D-FFs 800-1 to 800-4.

Here, the first to fourth D-FFs 800-1 to 800-4 may operate according to the plurality of first to fourth clock signals ref1 to ref4, respectively, from the DCO phase accumulation unit 600 as shown in FIG. 7.

Here, the first to fourth D-FFs 800-1 to 800-4 perform sampling operations according to the plurality of first to fourth clock signals ref1 to ref4, respectively, from the DCO phase accumulation unit 600, as shown in FIG. 7, in a sequential manner. Referring to an output signal Sout2 according to an exemplary embodiment of the invention as shown in FIG. 7, all of the first to fourth D-FFs 800-1 to 800-4 operate within one clock cycle.

On the other hand, as for the digital phase-locked loop in the related art, considering that an output signal Sout1 is output during the fourth clock cycle, as shown in FIG. 7, loop delay is remarkably reduced in the digital phase-locked loop according to the exemplary embodiment of the invention as shown by a comparison between the output signal Sout1 of the D-FF circuit of the digital phase-locked loop according to the exemplary embodiment of the invention and the output signal Sout2 of the D-FF circuit of the digital phase-locked loop according to the related art.

As described above, in the exemplary embodiment of invention, clock signals having various phases are used in order to reduce loop delay, and a circuit having a delay cell may operate at higher frequency than a loop.

Here, when multi-phase signals having various phases are used, a delay cell operates at higher frequency to thereby reduce loop delay. That is, according to an existing method, when a signal is transmitted from input to output, it takes time, determined by as the number of delay cells. However, by using multi-phase signals having various phases, an input signal can be transmitted to output in one cycle, thereby reducing loop delay.

Therefore, by using a signal having a higher frequency than a reference signal from a digital control oscillator, the loop delay of the all digital phase-locked loop is reduced, thereby preventing a reduction in reliability and reducing phase noise.

As set forth above, according to exemplary embodiments of the invention, delay in a closed loop of a digital phase-locked loop can be reduced by using multi-phase signals having phases and higher frequency that a reference signal.

While the present invention has been shown and described in connection with the exemplary embodiments, it will be apparent to those skilled in the art that modifications and variations can be made without departing from the spirit and scope of the invention as defined by the appended claims.

What is claimed is:

1. A digital phase-locked loop comprising:
a reference phase accumulation unit accumulating a predetermined division value according to a reference clock and sampling the predetermined division value being accumulated to thereby output a reference sampling phase value;
a phase detection unit detecting a phase difference signal corresponding to a difference value between the reference sampling phase value from the reference phase accumulation unit and a DCO sampling phase value;
a digital loop filter filtering and averaging the phase difference signal from the phase detection unit;
a digitally controlled oscillator generating an oscillation signal having a predetermined frequency on the basis of the phase difference signal averaged by the digital loop filter;
a DOC phase accumulation unit accumulating a predetermined reference value according to the oscillation signal from the digitally controlled oscillator, sampling the predetermined reference value being accumulated to thereby output the DCO sampling phase value, and generating a plurality of first to n-th D-FFs having the same frequency higher than a reference clock and different phases delayed in a sequential manner; and
first to n-th D-FFs included in a closed loop including the phase detection unit, the digital loop filter, the digitally controlled oscillator, and the DOC phase accumulation unit, and operating according to the plurality of first to n-th clock signals from the DCO phase accumulation unit, respectively.

2. The digital phase-locked loop of claim 1, wherein the DCO phase accumulation unit generates the plurality of first to n-th clock signals having the same frequency and different phases delayed in a sequential manner by using the oscillation signal.

3. The digital phase-locked loop of claim 2, wherein the DCO phase accumulation unit comprises:
an accumulator accumulating the predetermined reference value according to the oscillation signal from the digitally controlled oscillator; and
a D-FF sampling the predetermined reference value accumulated by the accumulator to thereby output the DCO sampling phase value,
wherein the accumulator generates the plurality of first to n-th clock signals having the same frequency and different phases delayed in a sequential manner by using the oscillation signal.

4. The digital phase-locked loop of claim 3, wherein the digital phase-locked loop further comprises a delta sigma modulator modulating the phase difference signal from the digital loop filter into a signal suitable for resolution of the digitally controlled oscillator.

5. The digital phase-locked loop of claim 4, wherein the delta sigma modulator comprises a plurality of D-FFs operating according to the plurality of first to n-th clock signals from the DCO phase accumulation unit.

6. The digital phase-locked loop of claim 5, wherein the DCO phase accumulation unit has a phase delay interval between a k-th clock signal and a k+1 clock signal among the plurality of first to n-th clock signals, which is shorter than one period of the first clock signal.

7. The digital phase-locked loop of claim 5, wherein the DCO phase accumulation unit has a phase delay interval between the first clock signal and the n-th clock signal among the plurality of first to n-th clock signals, which is shorter than one period of the first clock signal.
